(19) United States
(12) Patent Application Publication
(10) Pub. No.: US 2017/0164480 A1
(43) Pub. Date: Jun. 8, 2017

(54) TRANSFORMER HOLDER AND ELECTRONIC DEVICE USING THE SAME

(71) Applicants: LITE-ON ELECTRONICS (GUANGZHOU) LIMITED, GUANGZHOU (CN); LITE-ON TECHNOLOGY CORPORATION, TAIPEI CITY (TW)

(72) Inventors: Xiu-juan Liu, Nanjing city (CN); Li-min Du, Nanjing city (CN); Wei Wang, Nanjing city (CN); Zhi-hong Ye, Nanjing city (CN)

(21) Appl. No.: 15/201,538

(22) Filed: Jul. 4, 2016

(30) Foreign Application Priority Data
Dec. 8, 2015 (CN) 201521013651.0

(51) Int. Cl. H05K 1/18; H01F 27/24; H01F 27/32; H01F 27/28

(52) U.S. Cl. CPC H05K 1/182; H01F 27/28; H01F 27/24; H01F 27/325; H05K 2201/1003; H05K 2201/09072

(57) ABSTRACT

A transformer holder assembled with a transformer and placed into a through hole of a circuit board is provided, which includes a bottom wall and an annular side wall surrounding and connected to the periphery of the bottom wall. The bottom wall and the annular side wall together form an accommodating groove for containing the transformer. The transformer holder extends outward along left and right lateral edges of the annular side wall to respectively form a first flange and a second flange, and the first flange and the second flange cover a gap between an inner edge of the through hole of the circuit board and the annular side wall of the transformer holder.

### TECHNICAL FIELD

The present invention relates to a transformer, particularly a transformer holder designed to protect the transformer and prevent solder overflow, and an electronic device using such transformer holder.

### BACKGROUND ART

There is always a need to make electronic products, such as power supply products, thinner and lighter. In order to better utilize limited space, it is common to embed a transformer within a printed circuit board when making power supply products. Namely, the transformer is placed within an opening of the printed circuit board, and then undertakes a wave soldering process. However, since the magnetic core used in the transformer cannot endure high temperature during the soldering, it is necessary to use certain jigs to protect the transformer. By doing so, the jigs will occupy certain space of the printed circuit board, the cost is high, and it complicates the manufacturing process. To overcome these shortcomings, alternatively a high-temperature-resistant insulating base can be added in between the transformer and the printed circuit board. However, in order to avoid solder overflow (which could easily cause a short circuit and other risks) during the wave soldering process, it is imperative to make the gap between the transformer and the printed circuit board much smaller than 0.8 mm, which is not a feasible tolerance for mass production. As such, the bulky and costly jigs are still needed to prevent solder overflow during mass production.

Therefore, there is a need to address the above-mentioned problems by providing a new solution.

After extensive research and study, the present invention discloses a new design of power supply products to effectively address the above-mentioned drawbacks.

### SUMMARY OF THE INVENTION

One objective of the present invention is to provide a transformer holder and an electronic device using the same. In particular, using such a transformer holder the electronic device can (i) be manufactured without any tailor-made jigs, (ii) allow a magnetic core of the transformer to endure the heat during a wave soldering process, and (iii) further avoid solder overflow during the wave soldering process.

In order to achieve the objective described above, the present invention further discloses a transformer holder to be assembled with a transformer and placed into the through hole of a circuit board, and the transformer holder includes a bottom wall and an annular side wall. The annular side wall surrounds and is connected to the periphery of the bottom wall, and the bottom wall and the annular side wall together form an accommodating groove for containing the transformer; wherein the transformer holder extends outward along left and right lateral edges of the annular side wall to respectively form a first flange and a second flange which are used to cover a gap between an inner edge of the through hole of the circuit board and the annular side wall.

In order to achieve the objective described above, the present invention further provides an electronic device which includes a transformer, a transformer holder and a circuit board. The transformer holder includes a bottom wall and an annular side wall surrounding and being connected to the periphery of the bottom wall. The bottom wall and the annular side wall together form an accommodating groove for containing the transformer, and the transformer is accommodated in the accommodating groove. The circuit board is disposed with a through hole in which the transformer holder is placed. The transformer holder extends outward along left and right lateral edges of the annular side wall to respectively form a first flange and a second flange which extend horizontally to the upper surface of the circuit board and cover the gap between the inner edge of the through hole of the circuit board and the annular side wall.

With such a transformer holder the electronic device can (i) be manufactured without any tailor-made jigs; (ii) allow the magnetic core of the transformer to endure the heat during the wave soldering process through the accommodating groove formed together by the bottom wall and the annular side wall of the transformer holder; and (iii) avoid solder overflow during the wave soldering process by covering the gap between the inner edge of the through hole of the circuit board and the annular side wall by means of the first flange and the second flange .

In order to further understand the features and technical content of the present invention, reference can be made to the detailed description and accompanying drawings of the present invention. However, the accompanying drawings are only provided for reference and illustration, but not intended to limit the present invention.

### BRIEF DESCRIPTION OF DRAWINGS

FIG. 1 is an exploded view of a first preferred embodiment of the present invention. (I)

FIG. 2 is an exploded view of a first preferred embodiment of the present invention. (II)

FIG. 3 is a perspective view of a combination of the transformer and the transformer holder in a first preferred embodiment of the present invention.

FIG. 4 is a perspective view of a combination of the transformer, the transformer holder and the circuit board in a first preferred embodiment of the present invention.

FIG. 5 is a cross-sectional schematic view along section line V-V shown in FIG. 4.

FIG. 6 is an exploded view of a second preferred embodiment of the present invention.

FIG. 7 is a perspective view of a combination of the transformer, the transformer holder and the circuit board in the second preferred embodiment of the present invention.

FIG. 8 is a cross-sectional view along section line VIII-VIII shown in FIG. 7.

FIG. 9 is an exploded view of a third preferred embodiment of the present invention.

FIG. 10 is a perspective view of a combination of the transformer, the transformer holder and the circuit board in the third preferred embodiment of the present invention.

FIG. 11 is a cross-sectional view along section line XI-XI shown in FIG. 10.

### DETAILED DESCRIPTION OF THE PREFERRED EMBODIMENTS

Quantities or the like mentioned in the embodiments described below do not limit the scope of application of the present invention unless otherwise specified. Specific details disclosed herein should not be construed as limiting, but rather should be defined only as the basis for patent scope, and as a representative basis to provide teaching such that those skilled in the art may achieve an appropriate practical implementation of variations of the present utility model, including various features and combinations that may not be clearly disclosed herein. In addition, directional terms mentioned herein, such as left, right, up down etc., are merely directions in the reference drawings, and are intended to explain, and not limit, the present utility model.

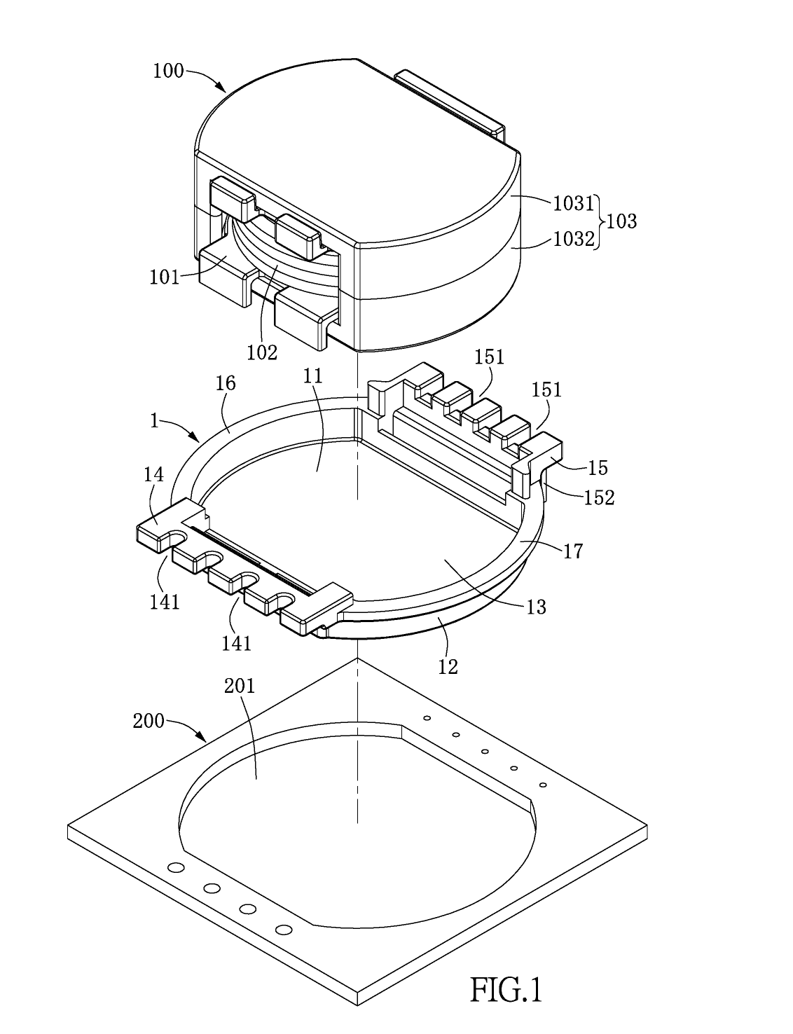

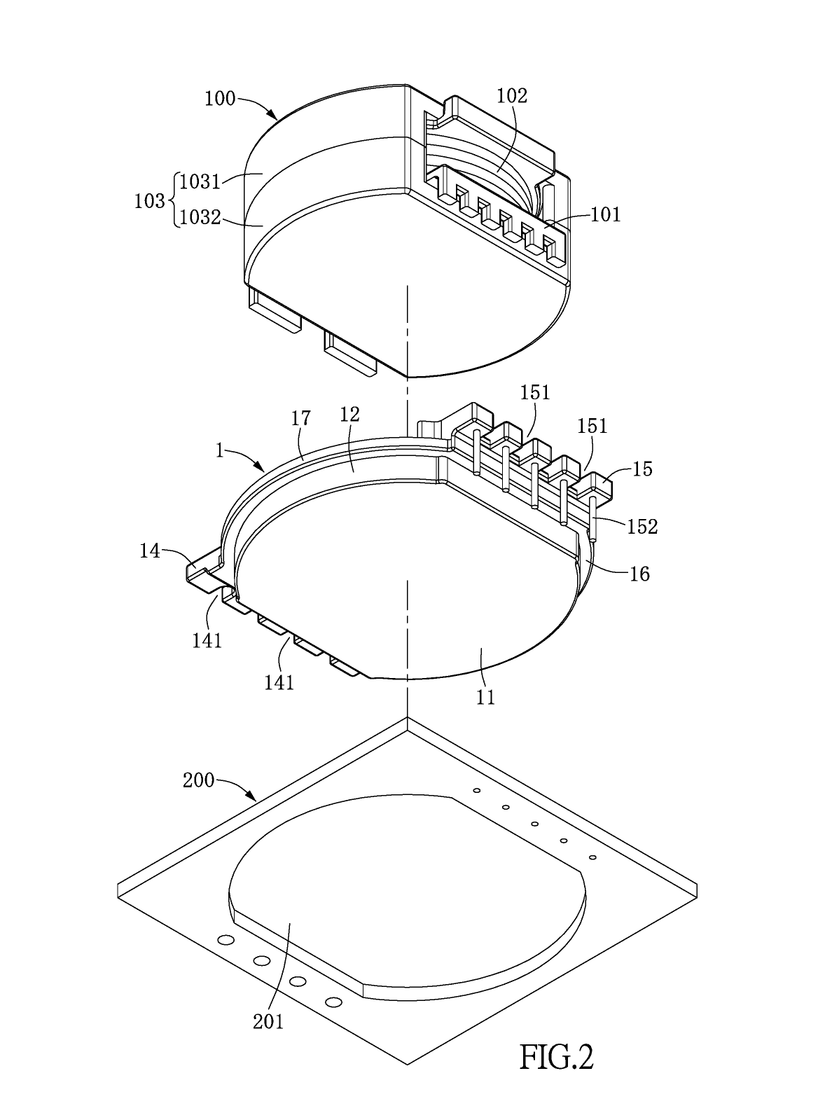

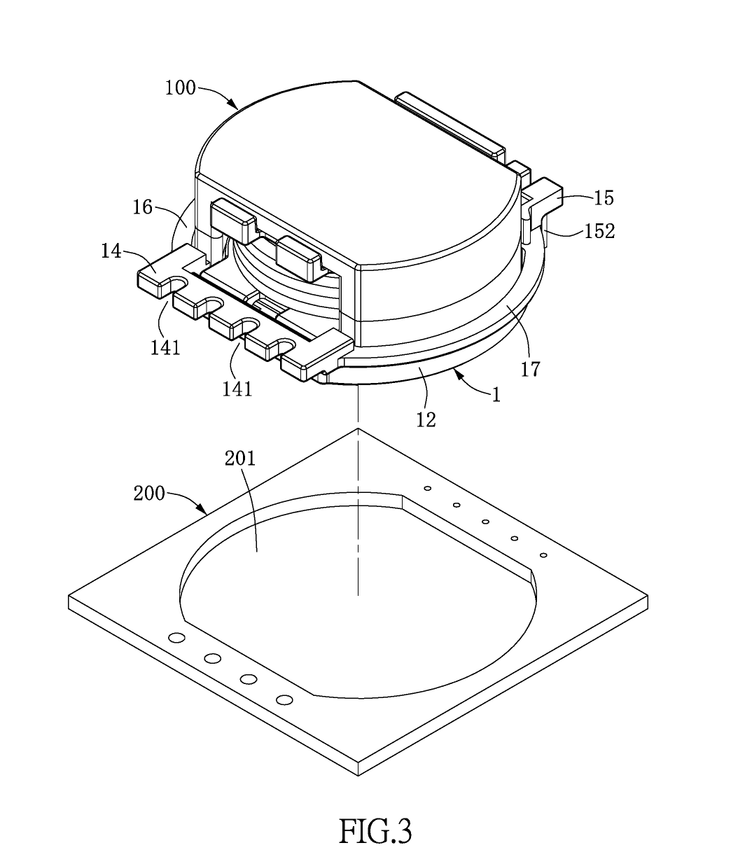

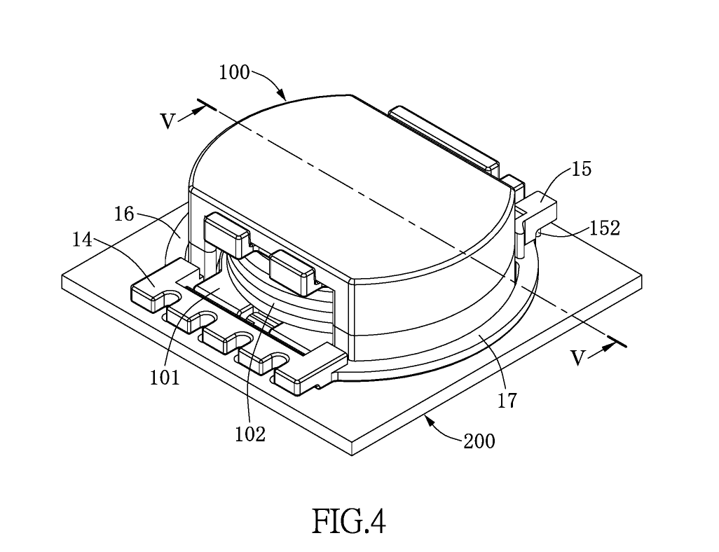

Please refer to FIG. 1 to FIG. 5. The first embodiment in this present invention provides a transformer holder 1 to be assembled with a transformer 100 and placed into through hole 201 of a circuit board 200.

The transformer 100 can include a bobbin 101, a coil 102 and a magnetic core group 103. The coil 102 is wound on the bobbin 101, and a plurality of wires (not shown), which can be designed according to actual need, protrude from the front and rear sides of the coil 102 respectively and the type of the coil 102 is not construed as limited to the embodiments set forth herein. The magnetic core group 103 includes an upper core 1031 and a lower core 1032, and the bobbin 101 is disposed between the upper core 1031 and the lower core 1032. Both of the upper core 1031 and lower core 1032 of the magnetic core group 103 are E-shaped and can be freely designed according to the actual needs of the design, and the type of the magnetic core group 103 is not construed as limited to the embodiments set forth herein.

In this embodiment, the coil 102 is wound on the bobbin 101, the bobbin 101 is disposed between the upper and lower cores 1031, 1032 of the magnetic core group 103, and one skilled in the art is able to freely design the manner of combination of the bobbin 101, the coil 102 and the magnetic core group 103. In this embodiment, the type of combination of the bobbin 101, the coil 102 and the magnetic core group 103 is not construed as limited to the embodiments set forth herein.

The circuit board 200 is a circuit board disposed on the electronic device (such as an electrical product, but the same is not construed as limited to the embodiments set forth herein), and the appearance, size and circuit layout of the circuit board can be freely designed according to the actual needs of the design and are not construed as limited to the embodiments set forth herein.

The transformer holder 1 can be made of a high-temperature-resistant insulating material, or similar materials. The transformer holder 1 includes a bottom wall 11 and an annular side wall 12. The annular side wall 12 surrounds and is connected to the periphery of the bottom wall 11, and the bottom wall 11 and the annular side wall 12 together form an accommodating groove 13 to accommodate the transformer 100. The shape of the accommodating groove 13 can correspond to the outer shape of the transformer 100, allowing the transformer 100 to be positioned and fixed in the accommodating groove 13.

Furthermore, the transformer holder 1 extends outward along the front and rear lateral edges of the annular side wall 12 to respectively form a first coil seat 14 and a second coil seat 15, and extends outward along left and right lateral edges of the annular side wall 12 to respectively form a first flange 16 and a second flange 17. Two ends of the first flange 16 are respectively connected to the first coil seat 14 and the second coil seat 15, and two ends of the second flange 17 are also respectively connected to the first coil seat 14 and the second coil seat 15.

To be specific, the first coil seat 14 is provided with a plurality of concave first limiting grooves 141 in sequence at intervals, and the second coil seat 15 is provided with a plurality of concave second limiting grooves 151 in sequence at intervals. The first limiting grooves 141 and the second limiting grooves 151 can respectively allow a plurality of first wires and second wires of the coil 102 to pass (not shown) in order to prevent the wires from contacting each other to easily cause a short circuit. In addition, the second coil seat 15 is disposed with a plurality of pins 152 to connect the second wires. It should be noted here that the number of the first limiting grooves 141, the second limiting grooves 151 and pins 152 are not construed as limited to the embodiments set forth herein and can be freely designed according to the actual needs of the design.

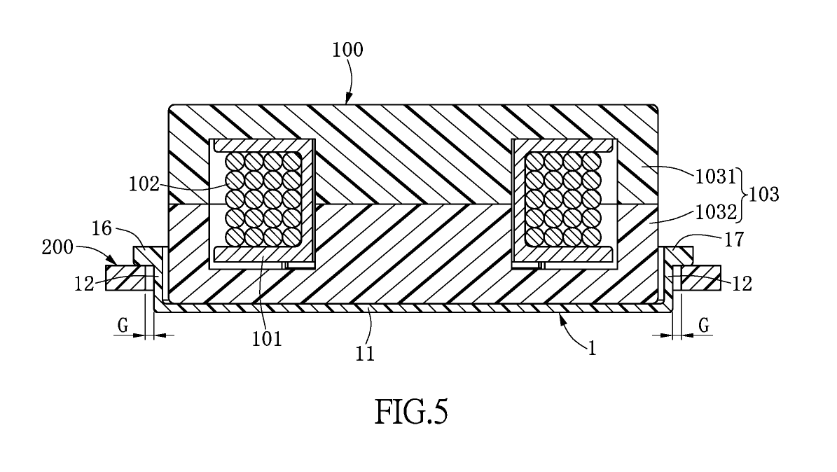

When the transformer holder 1 is placed into the through hole 201 of the circuit board 200, the first coil seat 14 and the second coil seat 15 can span and connect to the upper surface of the circuit board 200, and are fixedly welded to the circuit board 200 by the pins 152, because they are formed extending outward along front and rear lateral edges of the annular side wall 12 respectively. Here, the left and right lateral edges of the annular side wall 12 respectively form gaps G with the through hole 201 of the circuit board 200 (shown in FIG. 5). The first flange 16 and the second flange 17 can cover the gaps G formed between the inner edge of the through hole 201 of the circuit board 200 and the annular side wall 12, because they are formed extending outward along left and right lateral edges of the annular side wall 12 respectively.

The size of the gap G in this embodiment is not required to be smaller than 0.8 millimeters and can be up to 1.5 millimeters. Nevertheless, regardless of the size of the gap G, it suffices as long as the gap G can be covered by the first flange 16 and the second flange 17 which extend horizontally to the upper surface of the circuit board 200, such that the gap G is not exposed on the upper surface of the circuit board 200 to prevent solder overflow which may cause a short circuit.

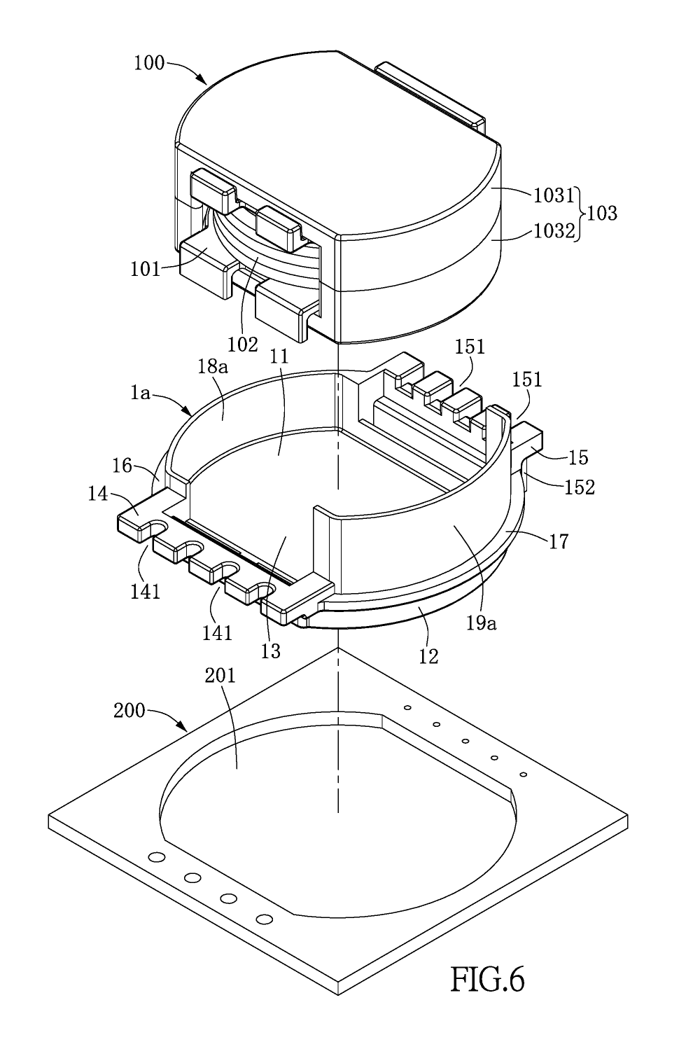

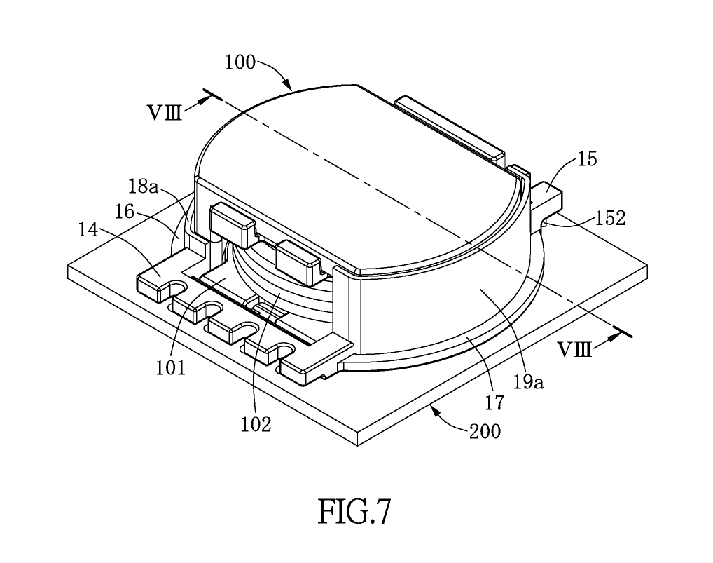

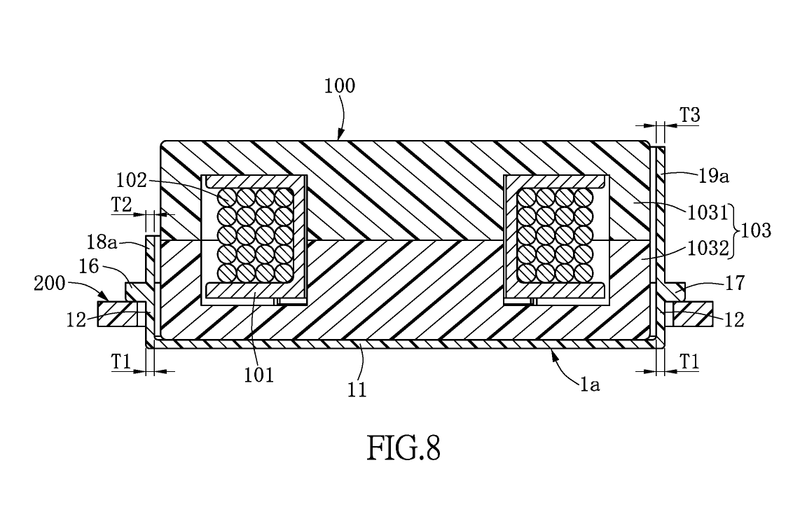

Please refer to FIG. 6 to FIG. 8. The second embodiment in the present invention is to provide a transformer holder 1a. The difference between this embodiment and the first embodiment is that a first insulating wall 18a and a second insulating wall 19a are formed extending upward along left and right lateral edges of the annular side wall 12 respectively, and a thickness T2 of the first insulating wall 18a and a thickness T3 of the second insulating wall 19a are respectively equal to a thickness T1 of the left and right sides of the annular side wall 12, such that the first flange 16 and the second flange 17 are respectively perpendicular to the first insulating wall 18a and the second insulating wall 19a. In this embodiment, the height between the top of the second insulating wall 19a and the bottom wall 11 is greater than the height between the top of the first insulating wall 18a and the bottom wall 11. Certainly, in other embodiments, the height between the top of the second insulating wall 19a and the bottom wall 11 can be equal to or less than the height between the top of the first insulating wall 18a and the bottom wall 11, but it is not limited thereto. The transformer 100 can be protected and the adjacent electronic components on the circuit board 200 can be provided with further insulating protection, because the first insulating wall 18a and the second insulating wall 19a can cover the two sides of the magnetic core group 103 of the transformer 100.

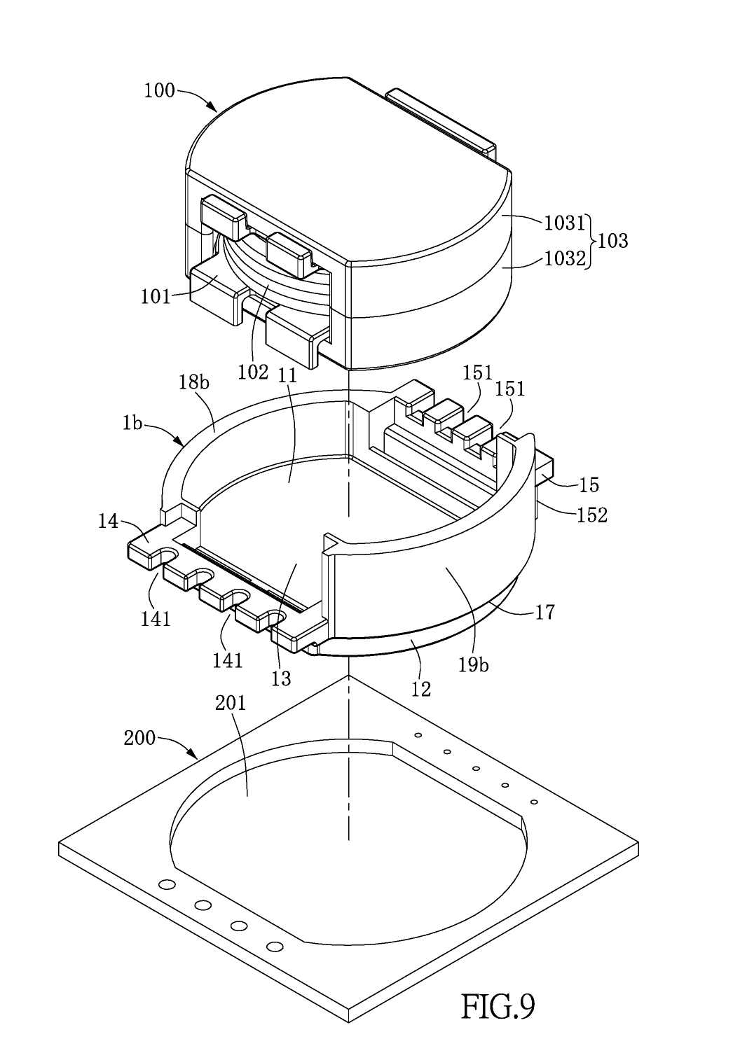

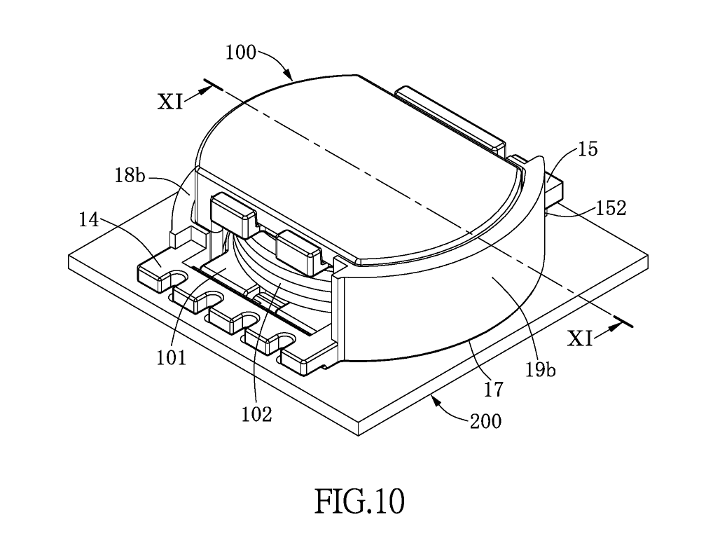

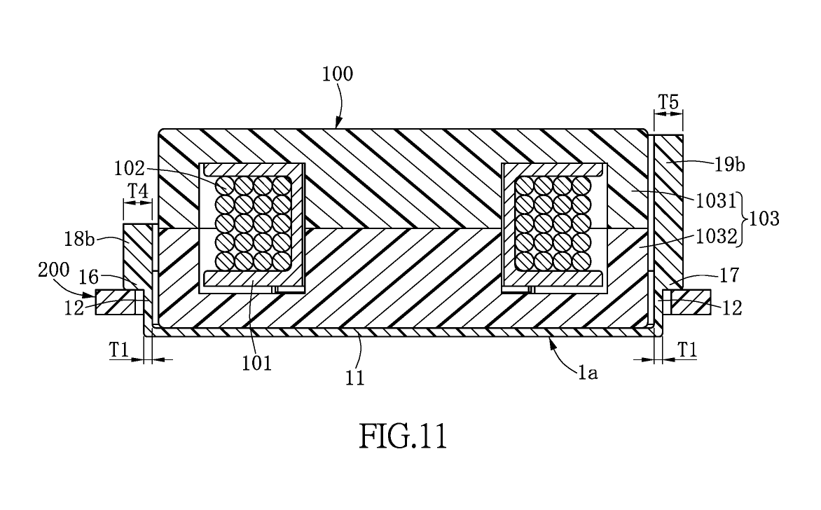

Please refer to FIG. 9 to FIG. 11. The third embodiment in the present invention is to provide a transformer holder 1b. The difference between this embodiment and the first embodiment is that the first insulating wall 18b and the second insulating wall 19b are formed extending upward along left and right lateral edges of the annular side wall 12 respectively, and a thickness T4 of the first insulating wall 18b and a thickness T5 of the second insulating wall 19b are respectively greater than the thickness T1 of the left and right sides of the annular side wall 12 and flush with the first flange 16 and the second flange 17, so that the first flange 16 and the second flange 17 respectively form integral extending structures with the first insulating wall 18b and the second insulating wall 19b. Similar to the second embodiment, the height between the top of the second insulating wall 19b and the bottom wall 11 is greater than the height between the top of the first insulating wall 18b and the bottom wall 11. Certainly, in other embodiments, the height between the top of the second insulating wall 19b and the bottom wall 11 can be equal to or less than the height between the top of the first insulating wall 18b and the bottom wall 11, and it shall not be limited thereto.

In summary, with such transformer holder the electronic device can (i) allow the magnetic core of the transformer to endure the heat during the wave soldering process by the accommodating groove which is formed by the bottom wall of the transformer holder and the annular side wall together and used to accommodate the transformer; (ii) avoid solder overflow during the wave soldering process by covering the gap between the inner edge of the through hole of the circuit board and the annular side wall by means of the first flange and the second flange and allow direct completion of the wave soldering process to be uninfluenced by manufacturing tolerance, and (iii) be manufactured without any tailor-made jigs. Thus it is unnecessary to make an extra protection fixture, thereby efficiently reducing occupied space and manufacturing costs.

The above description only provides preferred practical embodiments of the present invention, and is not intended to limit the scope of the present invention. All equivalent changes and modifications made according to the claims of the present invention should fall within the scope of the present invention.

What is claimed is:

1. A transformer holder to be assembled with a transformer and placed into a through hole of a circuit board and characterized by comprising: a bottom wall and an annular side wall surrounding and connected to the periphery of the bottom wall, and the bottom wall and the annular side wall together forming an accommodating groove for containing the transformer, wherein the transformer holder extends outward along left and right lateral edges of the annular side wall to respectively form a first flange and a second flange, and the first flange and the second flange cover a gap between an inner edge of the through hole of the circuit board and the annular side wall.

2. The transformer holder according to claim 1, wherein the transformer includes a bobbin, a coil and a magnetic core group, the coil is wound on the bobbin, and the bobbin is disposed between the magnetic core group.

3. The transformer holder according to claim 1, wherein the transformer holder extends outward along front and rear lateral edges of the annular side wall to respectively form a first coil seat and a second coil seat, and two ends of the first flange are respectively connected to the first coil seat and the second coil seat, and two ends of the second flange are respectively connected to the first coil seat and the second coil seat, and the first coil seat and the second coil seat are used to span to and connect to an upper surface of the circuit board.

4. The transformer holder according to claim 3, wherein the first coil seat has a plurality of first limiting grooves arranged at intervals, and the second coil seat has a plurality of second limiting grooves arranged at intervals.

5. The transformer holder according to claim 1, wherein the left and right lateral edges of the annular side wall extend upward to respectively form a first insulating wall and a second insulating wall, and the thicknesses of the first insulating wall and the second insulating wall are respectively equal to the thicknesses of the opposite left and right sides of the annular side wall, such that the first flange and the second flange are respectively perpendicular to the first insulating wall and the second insulating wall.

6. The transformer holder according to claim 1, wherein the left and right lateral edges of the annular side wall extend upward to respectively form a first insulating wall and a second insulating wall, and the thicknesses of the first insulating wall and the second insulating wall are each greater than the thickness of the opposite left and right sides of the annular side wall and flush with the first flange and the second flange, such that the first flange and the second flange form integrated extending structures respectively with the first insulating wall and the second insulating wall.

7. An electronic device, characterized by comprising:
a transformer;
a transformer holder including a bottom wall and an annular side wall, the annular side wall surrounding and being connected to the periphery of the bottom wall, the bottom wall and the annular side wall together forming an accommodating groove, and the transformer being accommodated in the accommodating groove; and
a circuit board having a through hole, and the transformer holder being placed into the through hole;
wherein the transformer holder extends outward along left and right lateral edges of the annular side wall to respectively form a first flange and a second flange, and the first flange and the second flange each extend horizontally to an upper surface of the circuit board and cover a gap between an inner edge of the through hole and the annular side wall.

8. The electronic device according to claim 7, wherein the transformer includes a bobbin, a coil and a magnetic core group, and the coil is wound on the bobbin, and the bobbin is disposed between the magnetic core group.

9. The electronic device according to claim 7, wherein the transformer holder extends outward along front and rear lateral edges of the annular side wall to respectively form a first coil seat and a second coil seat, and two ends of the first flange are respectively connected to the first coil seat and the second coil seat, and two ends of the second flange are respectively connected to the first coil seat and the second coil seat, and the first coil seat and the second coil seat span and connect to the upper surface of the circuit board.

10. The electronic device according to claim 9, wherein the first coil seat has a plurality of first limiting grooves arranged at intervals, and the second coil seat has a plurality of second limiting grooves arranged at intervals.

11. The electronic device according to claim 7, wherein the left and right lateral edges of the annular side wall extend upward to respectively form a first insulating wall and a second insulating wall, and the thicknesses of the first insulating wall and the second insulating wall are respectively equal to the thicknesses of the left and right sides of the side wall, such that the first flange and the second flange are respectively perpendicular to the first insulating wall and the second insulating wall.

12. The electronic device according to claim 7, wherein the left and right lateral edges of the annular side wall extend upward to respectively form a first insulating wall and a second insulating wall, and the thicknesses of the first insulating wall and the second insulating wall are each greater than the thickness of the left and right sides of the annular side wall and flush with the first flange and the second flange, such that the first flange and the second flange form integrated extending structures respectively with the first insulating wall and the second insulating wall.
